(19) United States
(12) Patent Application Publication
(10) Pub. No.: US 2026/0353617 A1
(43) Pub. Date: Nov. 5, 2026

(54) ELECTRICAL DEVICE

(71) Applicant: SEW-EURODRIVE GMBH & CO. KG, Bruchsal (DE)

(72) Inventors: Rolf JANZER, Bruchsal (DE); Horst FRANK, Öbstringen-Odenheim (DE)

(73) Assignee: SEW-EURODRIVE GMBH & CO. KG, Bruchsal (DE)

(21) Appl. No.: 19/484,589

(22) PCT Filed: Apr. 23, 2024
(86) PCT No.: PCT/EP2024/061076

§ 371 Date: Nov. 14, 2025

(30) Foreign Application Priority Data
May 16, 2023 (DE) 10 2023 002 005.2

(51) Int. Cl. H05K 7/20; H05K 7/14

(52) U.S. Cl. CPC H05K 7/209; H05K 7/1427

(57) ABSTRACT

An electrical device includes power electronics and signal electronics. The power electronics has a sheet metal housing having a cover to form a housing, the signal electronics has a signal electronics housing which is placed on the power electronics, and the cover has a connecting tab, through which a mating plug connector part of the power electronics projects. A plug connector part of the signal electronics is connected to the mating plug connector part, a guide groove is formed in the cover, and a guide rib formed on an inner side of the signal electronics housing projects into the guide groove. At least one first centering dome is arranged on the sheet metal housing and projects towards the signal electronics housing, and a screw projects through the centering dome, which also projects through the signal electronics housing and is screwed into a threaded bore of the power electronics. A hollow centering dome is formed on the connecting tab and towards the signal electronics housing, and a pin is formed on the signal electronics housing, which projects into the hollow centering dome.

### FIELD OF THE INVENTION

The present invention relates to an electrical device.

### BACKGROUND INFORMATION

In certain conventional systems, an electrical device has a heat-generating component, such as a power semiconductor, which is in contact with a heat sink for heat dissipation.

An electrical device is described in German Patent Document No. 10 2014 004 798.

### SUMMARY

Example embodiments of the present invention provide an electrical device, in which ready simple production and/or maintenance is possible.

According to example embodiments, an electrical device, e.g., a converter or inverter, has a power electronics, e. g., a power part, and a signal electronics, e.g., a control part. The power electronics has a sheet metal housing having a cover to form a housing. The signal electronics has a signal electronics housing which is placed on the power electronics, the cover has a connecting tab, through which a mating plug connector part of the power electronics projects, and a plug connector part of the signal electronics is connected to the mating plug connector part. A guide groove is formed in the cover, e. g., in which the guide groove extends parallel to the plug connection direction, and a guide rib formed on an inner side of the signal electronics housing projects into the guide groove and/or is guided thereby. At least one first centering dome is arranged on the sheet metal housing and projects towards the signal electronics housing, in which a screw projects through the centering dome, which also projects through the signal electronics housing and is screwed into a threaded bore of the power electronics. A hollow centering dome, e.g., formed from plastic, is formed on the connecting tab and projects towards the signal electronics housing, e. g., parallel to the plug connection direction of the plug connection formed from the plug connector part and the mating plug connector part. A pin, e.g., a cross pin, is formed on the signal electronics housing, which projects into the hollow centering dome, e.g., for centering the signal electronics housing relative to the sheet metal housing.

An advantage of this is that tilting is avoided when the signal electronics are placed on the power electronics, as the pin, the guide groove and the plug connection itself represent three centering devices with different modes of action. Overdetermination, but with different modes of action and thus differently directed tolerances, prevents tilting. The cover is a centrally important centering device, as it provides the majority of the centering devices.

According to example embodiments, the connecting tab on the cover is formed at an angle. An advantage of this is that different spatial directions are taken into account when aligning the signal electronics housing.

According to example embodiments, the cover is an injection-molded plastic part. An advantage of this is that ready, cost-effective production is possible, and the centering devices can be integrated by shaping without additional effort.

According to example embodiments, pegs formed on the cover and projecting therefrom extend into recesses or cut-outs in a base plate of the electrical device, the sheet metal housing is connected to the base plate, and a sheet metal edge of the sheet metal housing projects into a groove of the cover. For example, the sheet metal edge is pivoted into the groove by a pivoting movement about the connecting line of the pegs, e. g., when the electrical device is mounted, e.g., and thus projects into the groove. An advantage of this is that the smallest clear diameter of the recesses is larger than the largest outer diameter of the pegs. This allows the cover to be swiveled with the pegs plugged into the recesses. During this swivel movement, which is carried out after the pegs have been inserted into the recesses, the sheet metal edge is inserted into the groove, e.g., swiveled into it.

According to example embodiments, the cover has a knockout region, and, for example, a screw becomes accessible after the knockout region is knocked out, which screw secures an electrical ground connection or PE connection. An advantage of this is that this connection can be disconnected or closed without any other changes being made and that thus no testing, such as high-voltage testing or similar, is necessary.

According to example embodiments, the electrical device, e.g., the power electronics, includes a circuit board which is equipped with a heat-generating component, e. g., a power semiconductor, a heat sink having at least one cooling fin, and a housing part of the sheet metal. A bushing, e. g., a press-fit bushing, is plugged into a cut-out in the cooling fin, a screw, the screw head of which presses the printed circuit board, together with the component, towards the heat sink, is screwed into an internal thread of the bushing, and the bushing has a polyhedral region which is pressed into the housing part.

An advantage of this is that, on the one hand, the bushing is firmly connected to the housing part, and, on the other hand, when screwed into the bushing, the screw positions and/or presses the bushing against a step of the heat sink. This presses the printed circuit board with the component against the heat sink and improves and ensures heat transfer. At the same time, the screw together with the press-in nut serves as an electrical ground connection for the housing part in order to connect it to a conductive path on the printed circuit board.

To increase the safety of the electrical ground connection, the connection can optionally be implemented as a double connection and thus more securely.

According to example embodiments, the bushing has a toothing which is cut into the material of the cooling fin. The heat sink is thus also electrically securely connected to the bushing and thus also to the screw and the housing part, and is grounded, and a PE connection can also be implemented instead of the ground connection.

According to example embodiments, the toothing is an external toothing. An advantage of this is that the toothing cuts into the cut-out of the heat sink.

According to example embodiments, the screw projects through the heat sink, e.g., through the cooling fin. An advantage of this is that there is an electrical connection between the printed circuit board and the housing part.

According to example embodiments, the housing part is arranged on the side of the heat sink facing away from the printed circuit board and/or the printed circuit board is arranged on the side of the heat sink facing away from the housing part. An advantage of this is that the housing part can be electrically connected via the screw to a conductive path of the printed circuit board, which can be arranged on the other side of the heat sink in a mechanically protected manner.

According to example embodiments, the housing part is made as a punched and bent part from a sheet metal. An advantage of this is that ready production is possible.

According to example embodiments, the polyhedral region is arranged flush with the housing part on at least one side of the housing part, e. g., on the side of the housing part facing away from the heat sink.

According to example embodiments, the polyhedral region projects radially from the bushing. An advantage of this is that a high level of rotational safety can be achieved.

According to example embodiments, the polyhedral region is spaced from the toothing. An advantage of this is that the housing part is spaced from a step of the receiving region of the printed circuit board against which the bushing is positioned.

According to example embodiments, the cut-out is an interruption in the cooling fin. An advantage of this is that the cooling fin has a thickened region in which a bore is provided as a cut-out.

According to example embodiments, the bushing is made of steel. An advantage of this is that ready, cost-effective production is possible.

According to example embodiments, the heat sink is made of aluminum. An advantage of this is that the bushing cuts readily into the material of the heat sink.

According to example embodiments, the cooling fin has a thickening which is interrupted by the cut-out, e.g., the bushing is plugged into the cut-out and is thus received in the thickening. An advantage of this is that receiving the bushing is ready and safe.

According to example embodiments, a further bushing, e.g., a further press-fit bushing, is plugged into a further cut-out of a further cooling fin of the heat sink, a further screw, the screw head of which presses the printed circuit board, together with a further component, towards the heat sink, is screwed into an internal thread of the further bushing, the further bushing has a further polyhedral region which is also pressed into the housing part, the further bushing has a further toothing which is cut into the material of the further cooling fin, the further toothing is also an external toothing, and the further screw projects through the heat sink, e.g., through the further cooling fin. An advantage of this is that a sufficiently secure ground connection can be established. This is because the two screws act as an independently functioning electrical ground line or PE line.

If one of the screws fails, the respective other screw ensures that the function is maintained.

Further features and aspects of example embodiments of the present invention are explained in more detail below with reference to the appended schematic Figures.

### BRIEF DESCRIPTION OF THE DRAWINGS

FIG. 1 is a cross-sectional view through a region of an electrical device, in which a bushing 1 is used.

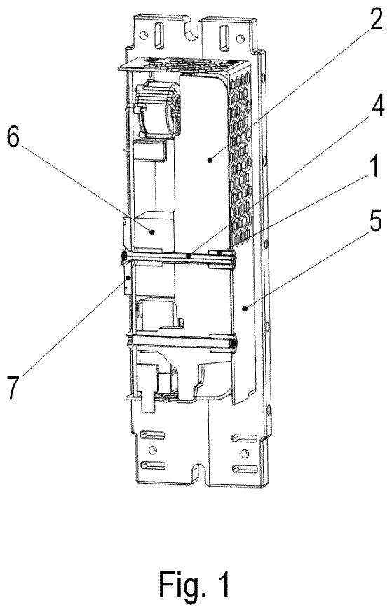

FIG. 2 is a perspective view of a portion region of the electrical device.

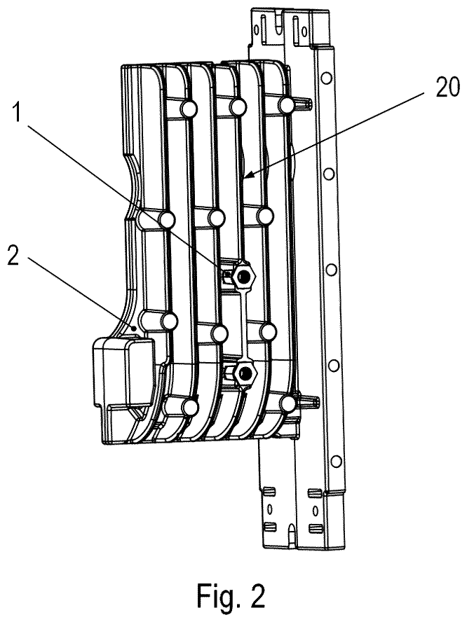

FIG. 3 is a perspective view of the bushing 1.

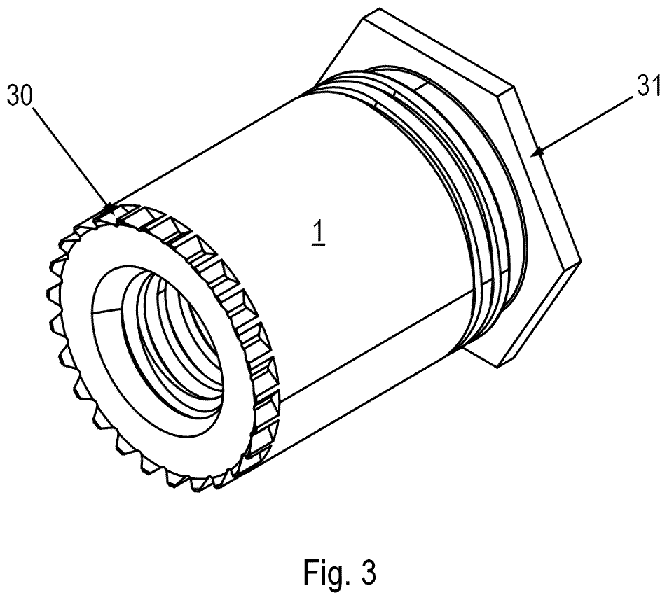

FIG. 4 illustrates the connection of the bushing 1 to a housing part 5 of the electrical device.

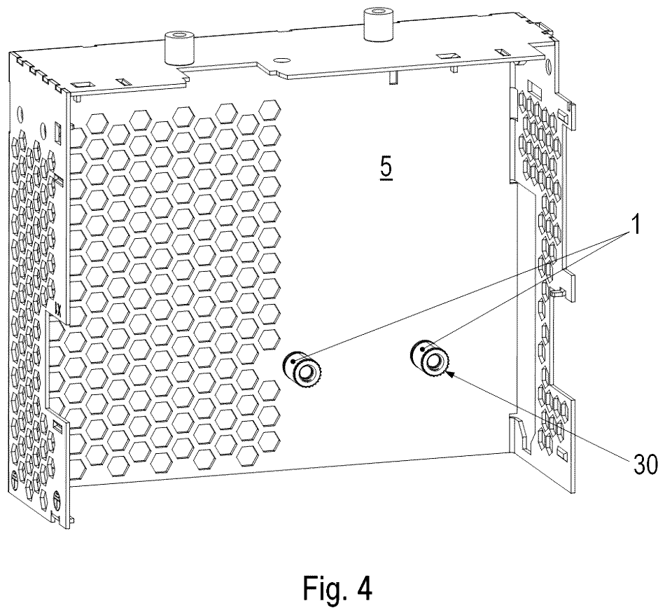

FIG. 5 is a perspective view of the signal electronics housing 50 of the electrical device.

FIG. 6 is a perspective view of a cover 60 of the electrical device.

FIG. 7 illustrates the cover 60 from a different viewing direction.

FIG. 8 is a perspective view of the electrical device without the signal electronics housing 50.

FIG. 9 is a perspective view of the electrical device.

### DETAILED DESCRIPTION

As illustrated in the Figures, the electrical device has a printed circuit board 3, which is pressed towards a heat sink 2 by the screw head of a screw 4.

Thus, a heat-generating component, e. g., a power semiconductor component, equipped on the printed circuit board 3 is pressed against the heat sink 2, e.g., to improve the thermal coupling of the component to the heat sink 2.

The bushing 1 is, for example, arranged as a press-fit bushing.

The bushing 1 is plugged into a cut-out, e. g., an interruption, of a cooling fin 20 of the heat sink 2 and has an internal thread into which a threaded section of the screw 4 is screwed, and the bushing 1 is supported in the cooling fin 20 at a step of the cooling fin 20.

The bushing 1 has a polyhedral region 31, e.g., a hexagonal region, which projects from the cooling fin 20 and is pressed into a housing part 5 made of sheet metal. Thus, the bushing 1 is embedded in the housing part 5 for conjoint rotation and connected for conjoint rotation with the housing part 5.

At the end region of the bushing 1 facing away from the polyhedral region 31, the bushing 1 has a toothing 30 with which the bushing 1 is plugged into the cooling fin 20 such that the toothing 30 is cut into the material of the cooling fin 20.

The heat sink 2 together with the cooling fin 20 is, for example, made of aluminum; the bushing 1 is, for example, made of steel.

The sheet metal of the housing part 5 is, for example, made of sheet steel. For example, the housing part 5 is arranged as a punched and bent part.

The toothing 30 is arranged as an external toothing.

The housing part 5 is, for example, arranged on the side of the heat sink 2 facing away from the printed circuit board 3.

The housing part 5 is detachably connected to the heat sink.

A pressure plate 7 is arranged between the screw head and the printed circuit board 3 so that the force flow introduced by the screw 4 is spread out and thus the printed circuit board 3 is protected against excessive pressure. The pressure plate 7 is, for example, made of metal so that the housing part 5 is electrically connected to a conductive path of the printed circuit board 3 via the metal bushing 1 and the metal screw 4 as well as the metal pressure plate 7. In this manner, a ground connection and/or PE connection can be provided for the housing part 5.

The screw axis of the screw 4 is oriented perpendicular to the direction in which the cooling fin 20 extends.

For example, the component is a power module including multiple power semiconductors.

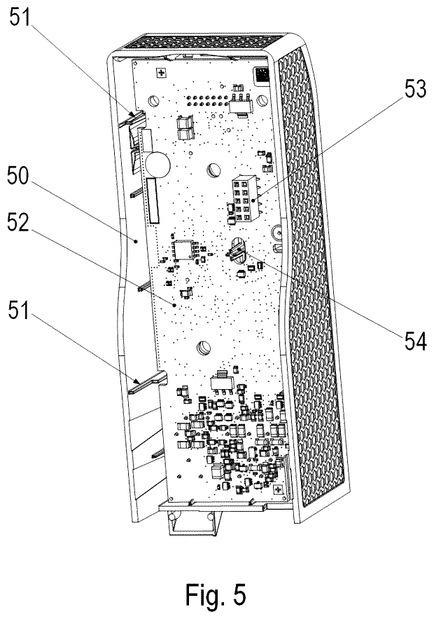

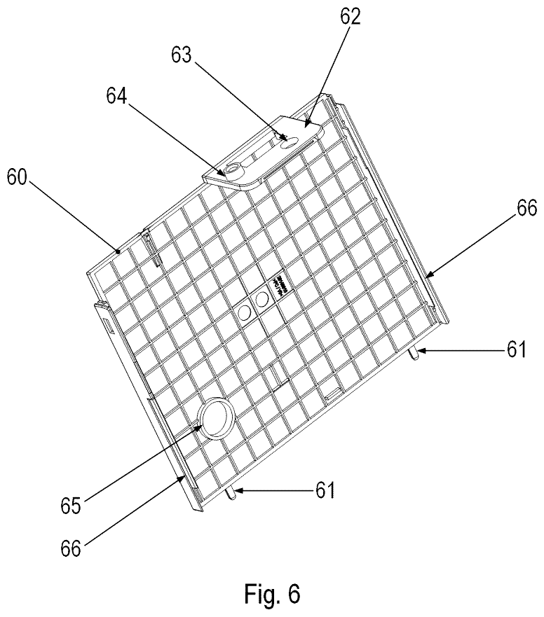

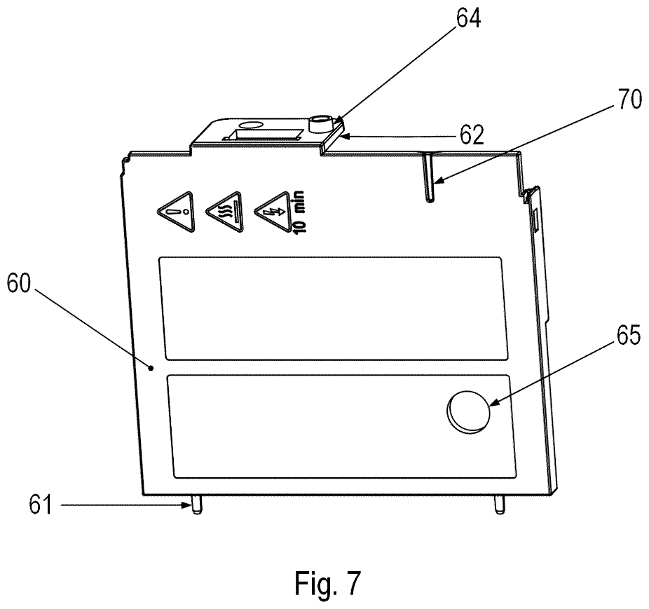

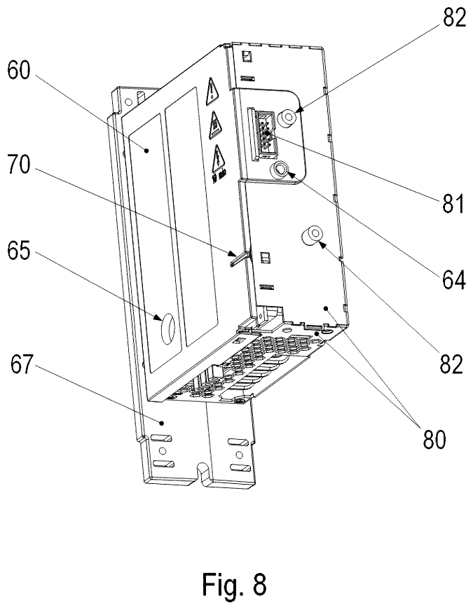

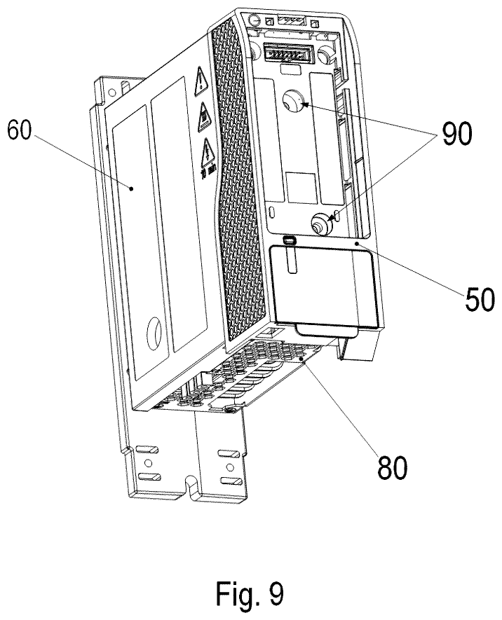

As illustrated in more detail in FIGS. 5 to 9, the electrical device, which is, for example, arranged as an inverter or converter, has a sheet metal housing 80 which surrounds the power electronics of the electrical device to form a housing and is suitable for installation in a switch cabinet. On one side of the electrical device, the sheet metal housing 80 is supplemented by a cover 60, e.g., a plastic cover, which is connected to the sheet metal housing 80, and on a bottom side by a base plate 67.

Signal electronics, e.g., the signal electronics housing 50, is mounted on the power electronics, e. g., on the sheet metal housing 80 together with the cover 60, and connected via screws.

The cover 60 is manufactured as an injection-molded plastic part and has projecting pegs 61, which are plugged into recesses in the base plate 67. By a pivoting movement about the connecting line of the pegs 61, sheet metal edges of the sheet metal housing 80 are pivoted into grooves 66 of the cover 60 during assembly of the electrical device.

Thus, at least one sheet metal edge projects into one of the grooves 66 of the cover 60. Similarly, a further sheet metal edge of the cover 60 projects into a further groove 66 of the cover 60. The cover 60 can thus be precisely aligned and centered in relation to the sheet metal housing 80.

At its end region facing away from the pegs 61, the cover 60 has a connecting tab 62, which is bent away from the rest of the cover 60 by a bending angle of 90°. This connecting tab 62 has a centering hole 63 passing through the connecting tab 62 and a projecting centering dome 64, which is hollow.

Thus, a first of the screws can be passed through the centering dome 64.

The cover 60 has a latching lug so that the cover 60 can be clip-connected to the sheet metal housing 80.

The sheet metal housing has at least two hollow centering domes 82, which are arranged as press-fit bushings or screw bushings and are connected to the sheet metal housing 80 correspondingly.

One of the centering domes 82 projects through the centering hole 63 and thus supports the centering of the cover to the sheet metal housing 80.

A second screw projects through the centering dome 82 projecting through the centering hole 63.

A mating plug connector part 81 projects through a further cut-out in the connecting tab 62.

The cover 60 has, on one of its sides, a guide groove 70, which guide groove 70 is oriented parallel to the plugging-on direction of the signal electronics.

When placing the signal electronics on the power electronics, the signal electronics housing 50 is guided such that tilting is prevented during placement.

For this purpose, the signal electronics housing 50 has at least one guide rib 51 on its inner side, which is received and guided in the guide groove 70, e.g., during placement of the signal electronics housing 50 on the sheet metal housing 80.

A printed circuit board 52 equipped with signal electronics components is received in the signal electronics housing 50. In addition, the printed circuit board 52 is equipped with a plug connector part 53, which is brought into plug connection with the mating plug connector part 81 of the power electronics, which mating plug connector part 81 projects through the connecting tab 62.

Tilting is further prevented by the fact that a cross pin 54, which is formed on the signal electronics housing 50, projects into the centering dome 64.

Thus, the spatial alignment of the plug connector housing 50 relative to the power part of the electrical device is effected by the guide rib 51 or multiple such ribs, which project into corresponding guide grooves of the power part, together with the cross pin 54, which is plugged into the centering dome 64, and the plug connector part 53, which is or will be plug-connected to the mating plug connector part 81.

In addition, the centering domes 82 project into corresponding cavities of the signal electronics, so that, for example, coming from the outside, screws can be screwed through the signal electronics and through the cavities of the signal electronics and through the centering domes 82 into corresponding internal threads of the power electronics.

The cover 60 thus provides pre-centering during placement of the signal electronics and also performs a housing function for the power electronics. In addition, an RFID tag, which is arranged in the power electronics, can be read unhindered, as the cover 60 is made of plastic.

The cover 60 is readily labeled. In addition, warning notices can also be provided when shaping the cover 60, as well as type plate nests, i.e., recesses that are suitable for attaching type plates.

The cover 60 is made of electrically insulating material.

The cover 60 also has a knockout region 60, so that after removing the knockout region 60 a screw of the power electronics can be actuated, e.g., rotated, via a tool, e.g., a screwdriver, and an electrical ground connection or electrical PE connection can be secured via the screw.

### LIST OF REFERENCE NUMERALS

1 Bushing, e. g., press-fit bushing
2 Heat sink
3 Printed circuit board
4 Screw
5 Housing part
6 Heat-generating component
7 Pressure plate
20 Cooling fin
30 Toothing
31 Polyhedral region, e.g., hexagonal region
50 Signal electronics housing
51 Guide rib
52 Printed circuit board with signal electronics components
53 Plug connector part
54 Cross pin
60 Cover, e. g., plastic cover
61 Peg
62 Connecting tab
63 Centering hole
64 Centering dome
65 Knockout region
66 Groove
67 Base plate
70 Guide groove
80 Sheet metal housing for power electronics
81 Mating plug connector part
82 Centering dome
90 Cut-out, passing through the signal electronics housing 50

1-15. (canceled)

16. An electrical device, comprising:
power electronics including a sheet metal housing having a cover configured to form a housing; and
signal electronics including a signal electronics housing arranged on the power electronics;
wherein the cover includes a connecting tab, through which a mating plug connector part of the power electronics projects;
wherein a plug connector part of the signal electronics is connected to the mating plug connector part;
wherein the cover includes a guide groove;
wherein an inner side of the signal electronics housing includes a guide rib that projects into and/or is guided by the guide groove;
wherein at least one first centering dome is arranged on the sheet metal housing and projects toward the signal electronics housing;
wherein a screw projects through the centering dome, projects through the signal electronics housing, and is screwed into a threaded bore of the power electronics,
wherein the connecting tab includes a hollow centering dome that projects toward the signal electronics housing; and
wherein the signal electronics housing includes a pin that projects into the hollow centering dome.

17. The electrical device according to claim 16, wherein the electrical device is arranged as a converter and/or an inverter.

18. The electrical device according to claim 16, wherein the power electronics includes a power part, the signal electronics includes a control part, the guide groove extends parallel to the plug connection direction, the hollow centering dome is made of plastic and projects toward the signal electronics housing parallel to a plug connection direction of a plug connection formed by the plug connector part and the mating plug connector part, the pin is arranged as a cross pin, and the pin centers the signal electronics housing relative to the sheet metal housing.

19. The electrical device according to claim 16, wherein the connecting tab on the cover is arranged at an angle.

20. The electrical device according to claim 16, wherein the cover is arranged an injection-molded plastic part.

21. The electrical device according to claim 16, wherein pegs formed on the cover and projecting from the cover extend into recesses and/or cut-outs in a base plate of the electrical device, the sheet metal housing is connected to the base plate, and a sheet metal edge of the sheet metal housing projects into a groove of the cover.

22. The electrical device according to claim 16, wherein the cover includes a knockout region.

23. The electrical device according to claim 22, wherein a screw that is accessible through the knockout region secures an electrical ground connection and/or a PE connection.

24. The electrical device according to claim 16, further comprising:
a printed circuit board equipped with a heat-generating component;
a heat sink including at least one cooling fin;
a housing part made of sheet metal;
a bushing arranged in a cut-out in the cooling fin and including a polyhedral region pressed into the housing part; and
wherein a screw screwed into an internal thread of the bushing and including a screw head that presses the printed circuit board, together with the component, toward the heat sink.

25. The electrical device according to claim 24, wherein the bushing includes a toothing that cuts into a material of the cooling fin.

26. The electrical device according to claim 25, wherein the toothing is arranged as an external toothing.

27. The electrical device according to claim 24, wherein the screw projects through the heat sink and/or through the cooling fin.

28. The electrical device according to claim 24, wherein the housing part is arranged on a side of the heat sink facing away from the printed circuit board and/or the printed circuit board is arranged on a side of the heat sink facing away from the housing part.

29. The electrical device according to claim 24, wherein the housing part is arranged as a punched and bent part from a metal sheet.

30. The electrical device according to claim 24, wherein the polyhedral region is arranged flush with the housing part on at least one side of the housing part and/or on a side of the housing part facing away from the heat sink.

31. The electrical device according to claim 24, wherein the polyhedral region projects radially from the bushing.

32. The electrical device according to claim 24, wherein the polyhedral region is spaced from the toothing.

33. The electrical device according to claim 24, wherein the cut-out is arranged as an interruption in the cooling fin.

34. The electrical device according to claim 24, wherein the bushing is made of steel and/or the heat sink is made of aluminum.

35. The electrical device according to claim 24, wherein the cooling fin includes a thickening interrupted by the cut-out and/or the bushing is arranged in the cut-out and is received in the thickening.

36. The electrical device according to claim 24, wherein a further bushing is arranged in a further cut-out of a further cooling fin of the heat sink, a further screw is screwed into an internal thread of the further bushing and includes a screw head that presses the printed circuit board, together with a further component, toward the heat sink, the further bushing includes a further polyhedral region pressed into the housing part, the further bushing includes a further toothing that cuts into a material of the further cooling fin, the further toothing is arranged an external toothing, and the further screw projects through the heat sink.
